(19) United States
(12) Patent Application Publication
(10) Pub. No.: US 2018/0233464 A1
(43) Pub. Date: Aug. 16, 2018

(54) SEMICONDUCTOR MODULE

(71) Applicant: KABUSHIKI KAISHA TOSHIBA, Tokyo (JP)

(72) Inventors: Nobumitsu TADA, Hachioji Tokyo (JP); Hiroaki ITO, Suginami Tokyo (JP); Kazuya KODANI, Kawasaki Kanagawa (JP); Toshiharu OHBU, Kawasaki Kanagawa (JP); Hiroki SEKIYA, Kawasaki Kanagawa (JP); Yuuji HISAZATO, Fuchu Tokyo (JP); Hitoshi MATSUMURA, Yokohama Kanagawa (JP)

(21) Appl. No.: 15/688,755

(22) Filed: Aug. 28, 2017

(30) Foreign Application Priority Data
Feb. 10, 2017 (JP) 2017-023206

(51) Int. Cl. H01L 23/64; H01L 23/053; H01L 23/492; H01L 23/373; H01L 23/00; H01L 25/07

(52) U.S. Cl. CPC H01L 23/645; H01L 23/053; H01L 23/492; H01L 23/3735; H01L 24/48; H02M 7/003; H01L 2224/48225; H01L 2224/48747; H01L 2924/13055; H01L 2924/30107; H01L 2924/351; H01L 25/072

(57) ABSTRACT

A semiconductor modules includes insulating substrates having first and second patterns thereon. One terminal plate connects the first patterns and another terminal plate connects the second patterns. A first and a second switching chip are provided on the first pattern. Bonding wires connect the first ans second chips to the second pattern. An insulating plate with an auxillary conductor theron is disposed on the first pattern between the second pattern and both the first and second chips. A first auxiliary connection connect the auxiliary conductor and the second chip and a second auxilliary connection connect thes auxiliary conductor and the second pattern. The auxiliary connections may be, for example, bonding wires or solder connections.

### CROSS-REFERENCE TO RELATED APPLICATION

This application is based upon and claims the benefit of priority from Japanese Patent Application No. 2017-023206, filed Feb. 10, 2017, the entire contents of which are incorporated herein by reference.

### FIELD

Embodiments described herein relate generally to a semiconductor module.

### BACKGROUND

A high capacity inverter device can be formed with a module that includes a plurality of switching chips. It is desirable that the differences in impedance in connections of the chips within the module be small so as to suppress oscillation.

### DESCRIPTION OF THE DRAWINGS

FIG. 1 is a perspective diagram of a semiconductor module according to a first embodiment.

FIG. 2 is a perspective diagram illustrating an internal structure of the semiconductor module according to the first embodiment.

FIG. 3 is a perspective diagram illustrating an internal structure of a portion of the semiconductor module according to the first embodiment.

FIG. 4 is a partially exploded perspective diagram of the portion of the semiconductor module that is illustrated in FIG. 3.

FIG. 5 is a perspective diagram and an exploded perspective diagram of positive and negative electrode terminals of the semiconductor module according to the first embodiment.

FIG. 6 is a perspective diagram illustrating aspects of an internal structure of the portion of the semiconductor module according to the first embodiment.

FIG. 7 is a plan view diagram illustrating aspects of the internal structure of the portion of the semiconductor module according to the first embodiment.

FIG. 8 is a partially exploded perspective diagram of the internal structure of the portion of the semiconductor module illustrated in FIG. 6.

FIG. 9 is a perspective diagram illustrating aspects of an internal structure of a portion of the semiconductor module according to a second embodiment.

FIG. 10 is a perspective diagram illustrating aspects of an internal structure of a portion of the semiconductor module according to a third embodiment.

FIG. 11 is a perspective diagram illustrating aspects of an internal structure of a portion of the semiconductor module according to a fourth embodiment.

FIG. 12 is a perspective diagram illustrating an internal structure of a portion of a semiconductor module according to a comparative example.

FIG. 13 is a perspective diagram illustrating aspects of the internal structure of the portion of the semiconductor module of FIG. 12.

### DETAILED DESCRIPTION

In general, according to one embodiment, there is provided a semiconductor module including: a plurality of insulating substrates each having a first conductive pattern and a second conductive pattern on a surface thereof, a positive electrode terminal plate that electrically connects first conductive patterns on a pair of neighboring insulating substrates of the plurality of insulating substrates, a negative electrode terminal plate that electrically connects second conductive patterns on the pair of neighboring insulating substrates, the negative electrode terminal plate being connected to a negative electrode terminal connection portion of each second conductive pattern on the pair of neighboring insulating substrates, a first switching chip on a first conductive pattern of one of the pair of neighboring insulating substrate and having a front surface electrode on side of the first switching chip facing away from the first conductive pattern, a second switching chip on the first conductive pattern, the first switching chip being between the negative electrode terminal connection portion and the second switching chip, the second switching chip having a front surface electrode, a first bonding wire that connects the front surface electrode of the first switching chip and the second conductive pattern, a second bonding wire that connects the front surface electrode of the second switching chip and the second conductive pattern, an insulating plate on the first conductive pattern and between both the first and second switching chips and the second conductive pattern, an auxiliary conductor on the insulating plate, a first auxiliary connection that electrically connects the auxiliary conductor and the front surface electrode of the second switching chip, and a second auxiliary connection that connects the auxiliary conductor and the second conductive pattern.

Example embodiments will be described below with reference to the drawings. In the following description, substantially similar elements or components are given the same reference numerals, and descriptions of repeated elements or component may be omitted.

### First Embodiment

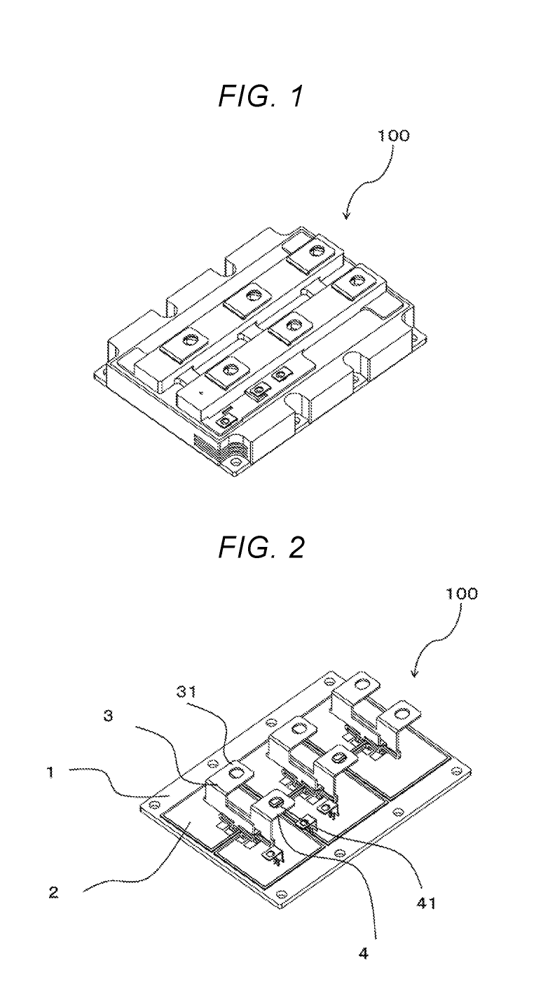

A semiconductor module 100 according to a first embodiment is described with reference to FIGS. 1 to 8.

FIG. 1 is a perspective diagram of the semiconductor module 100. FIG. 2 is a perspective diagram illustrating an internal structure of the semiconductor module according to the first embodiment.

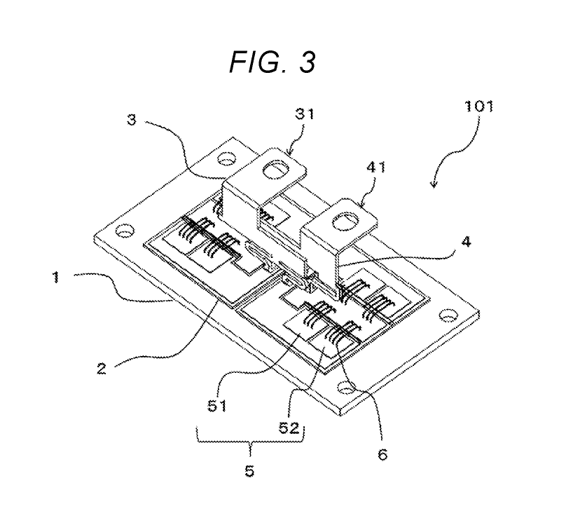

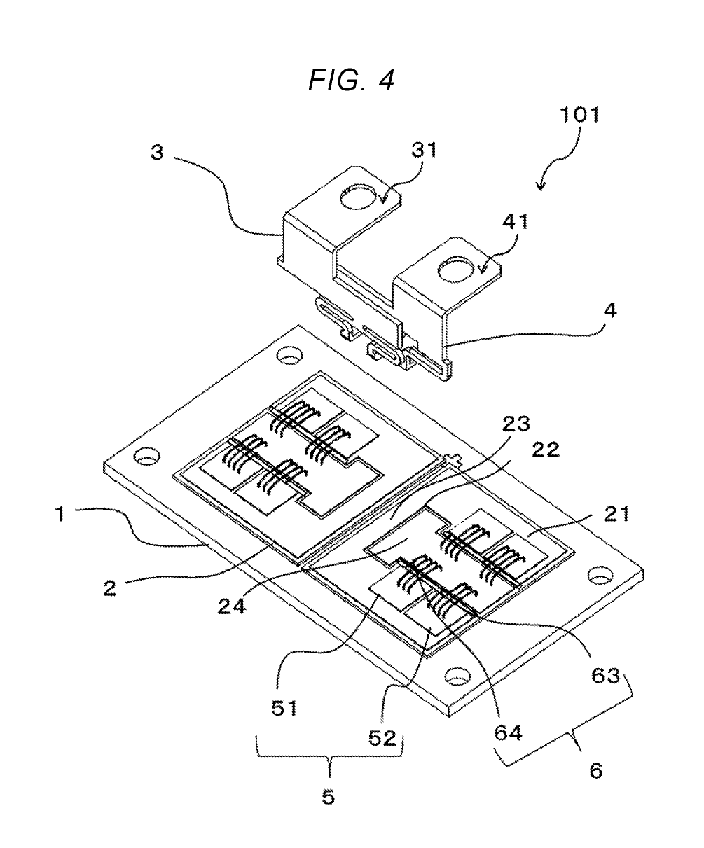

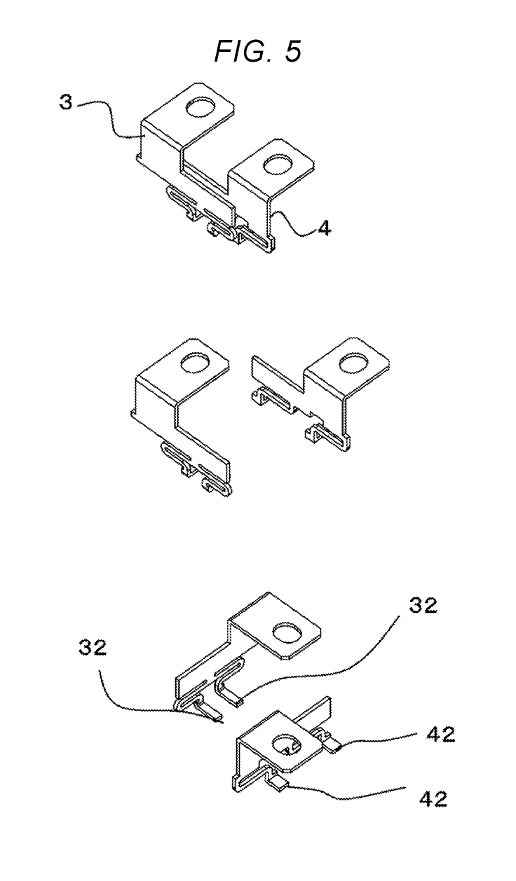

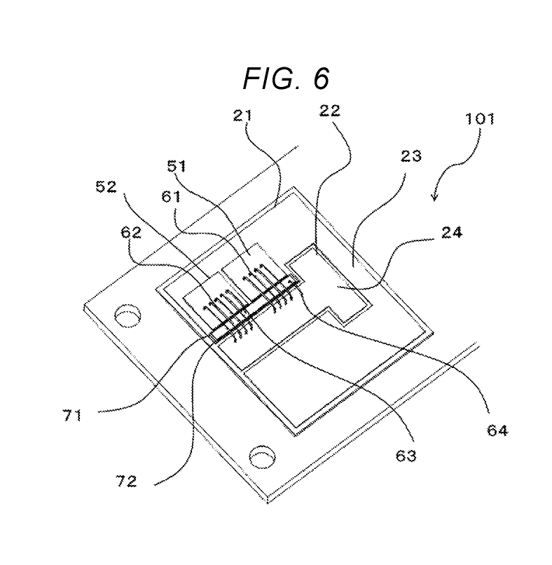

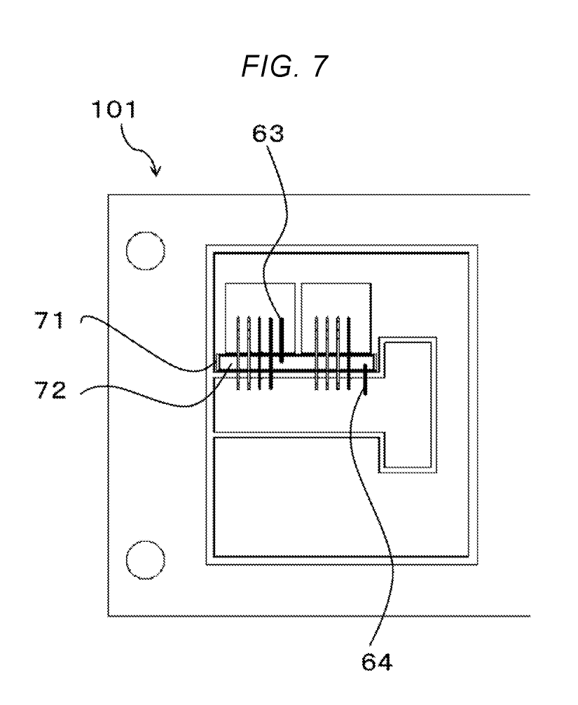

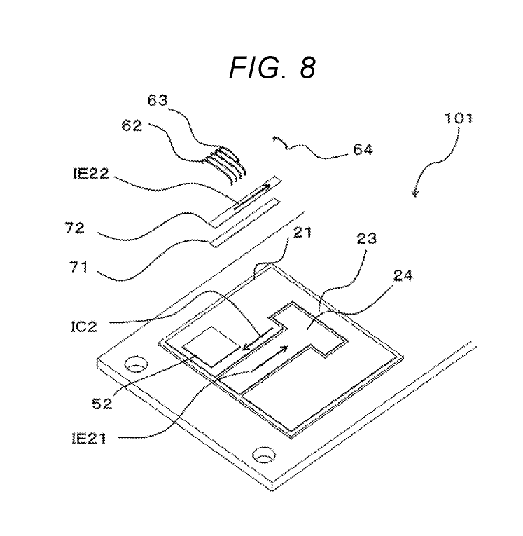

FIG. 3 is a perspective diagram illustrating an internal structure of a model portion 101 of the semiconductor module 100, which as depicted in FIG. 2, is repeated three times in the semiconductor module 100. FIG. 4 is a partially exploded perspective diagram of the inside of the model portion 101 that is illustrated in FIG. 3. FIG. 5 is a perspective diagram illustrating one portion of an internal structure of the model portion 101. FIG. 6 is a perspective diagram illustrating one portion of the internal structure of the model portion 101. FIG. 7 is an upper surface diagram illustrating one portion of the internal structure of the model portion 101. Furthermore, FIG. 8 is a partially exploded perspective diagram of the model portion 101 that is illustrated in FIG. 6.

In terms of structure, as illustrated in FIG. 1, the semiconductor module 100 is sealed with resin or the like. It is noted that in the present specification, the term “module” indicates the semiconductor module 100 is sealed with resin or the like. FIG. 2 illustrates an internal structure of the semiconductor module 100 from which resin is removed. An insulating substrate 2 mounted in the semiconductor module 100 is provided on a base plate 1 that has good heat conductivity. The insulating substrate 2 has a configuration in which a copper foil pattern is formed on the front surface side and on the rear surface side a heat insulating plate is provided. The heat insulating plate may be a material such as ceramic.

The semiconductor module 100 illustrated in FIG. 2 uses six insulating substrates 2. A positive electrode terminal plate 3 is for providing a connection between positive electrode copper foil patterns of two insulating substrates 2. Furthermore, the positive electrode terminal plate 3 has a protrusion portion that is a positive electrode terminal 31. A negative electrode terminal plate 4 is for providing a connection between negative electrode copper foil patterns of two insulating substrates 2. Furthermore, the negative electrode terminal plate 4 has a protrusion portion that is a negative electrode terminal 41.

The positive electrode terminal plate 3 and the negative electrode terminal plate 4 are provided in a pair. In the first embodiment, three sets of the positive electrode terminal plate 3 and the negative electrode terminal plate 4 are provided. Each positive electrode terminal plate 3 is provided on two adjacent insulating substrates 2. It is noted that these positive electrode terminals 3 are not electrically connected to each other inside of the semiconductor module 100. Each of the three negative electrode terminal plates 4 is provided in the same manner as the positive electrode terminal plate 3. Positive electrode terminal plates 3 or negative electrode terminal plates 4 are electrically connected to outside of the semiconductor module 100.

In the semiconductor module 100 two insulating substrates 2 and one set of positive electrode terminal plate 3 and negative electrode terminal plate 4 can be regarded as a unit of configuration. FIG. 3 illustrates such a unit of configuration, which is also referred to as a model portion 101 of the semiconductor module 100.

As illustrated in FIG. 3, a plurality of switching chips 5 are mounted on a copper foil pattern of the front surface of the insulating substrate 2. A front surface electrode of the switching chip 5 and the copper foil pattern are connected to each other with a bonding wire 6 made of aluminum. The wire 6 is a single thin wire with a circular cross section, and a plurality of wires 6 can be provided in parallel.

The wire 6 is an approximately arch-shaped line, and for example, four wires 6 are provided to each switching chip 5. The wire 6 may not necessarily be arc-shaped and may be shaped like a sine curve.

FIG. 4 is an exploded perspective diagram of the model portion 101, and illustrates a state before the positive electrode terminal plate 3 and the negative electrode terminal plate 4 are provided on two neighboring insulating substrates 2.

The positive electrode terminal 31 of the positive electrode terminal plate 3, and the negative electrode terminal 41 of the negative electrode terminal plate 4 protrude to the outside of the module. The positive electrode terminal 31 and the negative electrode terminal 41 are separated from each other in order to secure a space for insulation. It is noted that although not specifically illustrated, a deposited insulating layer material may be provided between the positive electrode terminal plate 3 and the negative electrode terminal plate 4 in order to secure insulation.

Furthermore, shapes of the positive electrode terminal plate 3 and the negative electrode terminal plate 4 are illustrated in FIG. 5. The positive electrode terminal plate 3 and the negative electrode terminal plate 4 have a positive electrode connection portion 32 and the negative electrode connection portion 42, respectively, which are on the insulating substrate 2 side. The positive electrode connection portion 32 and the negative electrode connection portion 42 have the shape of a U letter in order to alleviate stress.

The thickness of each of the positive electrode terminal plate 3 and the negative electrode terminal plate 4, or a distance between the positive electrode terminal plate 3 and the negative electrode terminal plate 4 can be suitably adjusted in such a manner that the positive electrode terminal plate 3 and the negative electrode terminal plate 4 are not too close to each other when factors such as thermal stress, mechanical vibration, and assembly variation are considered.

The insulating substrate 2 and a bonding wire 6 that are wiring members of the switching chip 5 are described here.

As illustrated in FIG. 4, the insulating substrate 2 has a first substrate pattern 21 and a second substrate pattern 22). Each substrate pattern is a conductive wiring pattern. Furthermore, a positive electrode terminal connection portion 23 and a negative electrode terminal connection portion 24 are provided on one portion of the first substrate pattern 21 and one portion of the second substrate pattern 22, respectively. The positive electrode connection portion 32 and the negative electrode connection portion 42 are connected to the positive electrode terminal connection portion 23 and the negative electrode terminal connection portion 24, respectively, and the semiconductor module 100, as illustrated in FIG. 2, is formed. In other words, the first substrate pattern 21 is connected to the positive electrode terminal plate 3 through the positive electrode terminal connection portion 23, and the second substrate pattern 22 is connected to the negative electrode terminal plate 4 through the negative electrode terminal connection portion 24.

Two switching chips 5 that are arranged adjacent to each other are connected to the first substrate pattern 21. The positive electrode terminal plate 3 is connected to the first substrate pattern 21 through the positive electrode terminal connection portion 23. The front surface electrode of the switching chip 5 is connected to the second substrate pattern 22 by the bonding wire 6. The second substrate pattern 22 is connected to the negative electrode terminal plate 4 through the negative electrode terminal connection portion 24.

As illustrated in FIGS. 6 and 7, an auxiliary conductor 72 is provided on the first substrate pattern 21 through an insulating plate 71. A front surface electrode of a second switching chip 52 and the auxiliary conductor 72 are connected to each other by a first auxiliary bonding wire 63. Furthermore, the auxiliary conductor 72 and the second substrate pattern 22 are connected to each other by a second auxiliary bonding wire 64 in the vicinity of a first switching chip 51. It is noted that the first switching chip 51 is closer to the negative electrode terminal connection portion 24 than is the second switching chip 52.

A bonding wire 61 is connected to the first switching chip 51 and a second pattern 22. Furthermore, a bonding wire 62 is connected to the second switching chip 52 and the second pattern 22. The bonding wires 61 and 62 are spaced away from each other for insulation. It is noted that in a case where a single wire is used for the bonding wires 61 and 62, the bonding wires 61 and 62 themselves expands and contracts due to a change in temperature in a process of manufacturing the semiconductor module 100 and in an in-use stage. Because a linear expansion coefficient of the switching chip 5 and the insulating substrate 2, to which the bonding wires 61 and 62 are connected, can be different, there is a likelihood that stress will be applied to the bonding wires 61 and 62. For this reason, the bonding wires 61 and 62 can be provided in the shape of a loop, and thus prevent excessive stress from being placed on the bonding wires.

For the first switching chip 51 and the second switching chip 52, wiring paths that run from the front surface electrode of the switching chip 5 to the negative electrode terminal connection portion 24 are as follows.

First, electric current flows from a front surface electrode of the first switching chip 51 to the negative electrode terminal connection portion 24 through the bonding wire 6 and the second substrate pattern 22.

On the other hand, for the second switching chip 52, the wiring path is as follows.

Electric current flows from the front surface electrode of the second switching chip 52 to the negative electrode terminal connection portion 24 through the bonding wire 6 and the second substrate pattern 22. Additionally, electric current also flows along a path that runs from the front surface of the second switching chip 52 to the negative electrode terminal connection portion 24 through the first auxiliary bonding wire 63, the auxiliary conductor 72, the second auxiliary bonding wire 64, and the second pattern 22.

The insulating plate 71 is an insulating plate for achieving electrical insulation between the first substrate pattern 21 and the auxiliary conductor 72. As the insulating plate 71, a thin plate of resin or ceramic is used.

The auxiliary conductor 72 is formed from a thin plate of metal that is an electric conductor, for example, copper, aluminum, and the like.

In the same manner as the bonding wires 61 and 62, the auxiliary bonding wires 63 and 64 are configured with aluminum or the like.

In the present embodiment, both of the auxiliary bonding wires 63 and 64 illustrate a state where only one single wire line is present, but may be configured to include a plurality of wire lines that are arranged in parallel, like the bonding wires 61 and 62.

### Operations and Effects

Next, operations and effects by the semiconductor module 100 according to the first embodiment are described using a comparative example.

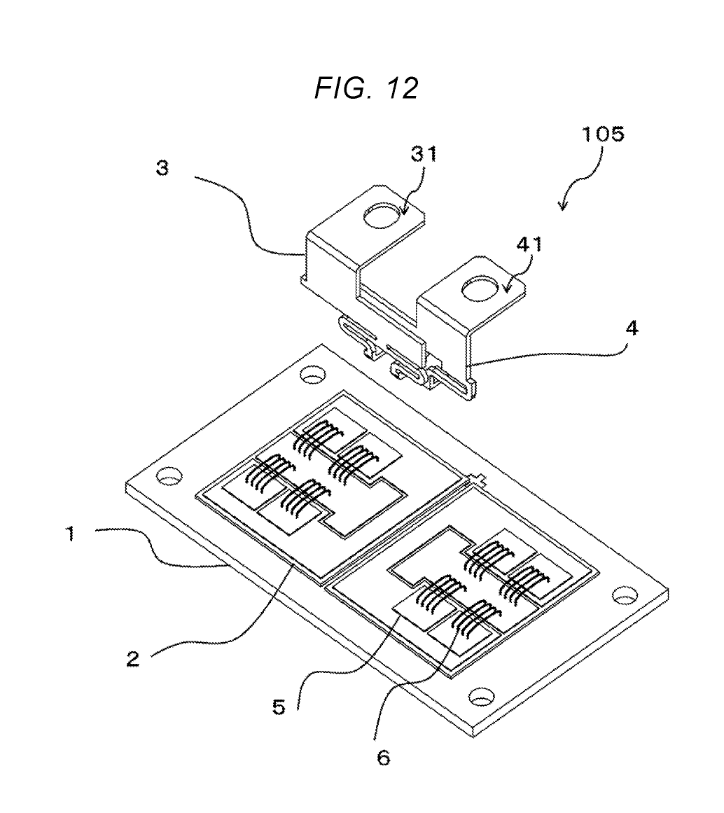

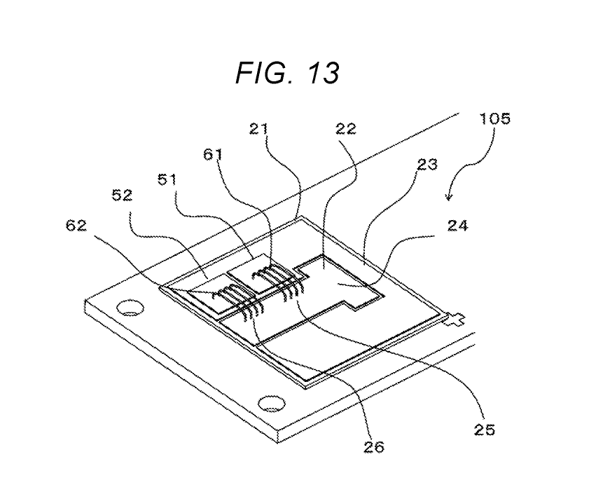

FIG. 12 illustrates an internal structure of the model portion 105 of the semiconductor module according to a comparative example. FIG. 13 is a perspective diagram illustrating one portion of FIG. 12. A description is provided with a focus on what is different from the first embodiment.

As illustrated in FIGS. 12 and 13, an electricity-flowing path is formed that runs from the positive electrode terminal 31 of the positive electrode terminal plate 3 to the negative electrode terminal 41 of the negative electrode terminal plate 4, through the positive electrode terminal plate 3, the first substrate pattern 21, the switching chip 5, the bonding wire 6, the second substrate pattern 22, and the negative electrode terminal plate 4.

The first substrate pattern 21 has two portions that are branched from the positive electrode terminal connection portion 23 to which the positive electrode terminal plate 3 is connected. The first switching chip 51 and the second switching chip 52 are installed on the two portions, respectively. The second switching chip 52 is provided farther away from the positive electrode terminal connection portion 23 than the first switching chip 51. That is, an electric current-flowing path from the positive electrode terminal connection portion 23 to the second switching chip 52 is longer than an electric current-flowing path from the positive electrode terminal connection portion 23 to the first switching chip 51.

Furthermore, the negative electrode terminal connection portion 24 that is one portion of the second substrate pattern is positioned between the positive electrode terminal connection portion 23 and the first switching chip 51. The other portions of the second substrate pattern 22 extend from the negative electrode terminal connection portion 24, and are connected to the switching chip 5 through the bonding wires 61 and 62. The bonding wire 62 that is connected to the second switching chip 52 is provided farther away from the negative electrode terminal connection portion 24 than the bonding wire 61 that is connected to the first switching chip 51. That is, an electric current-flowing path from the second switching chip 52 to the negative electrode terminal connection portion 24 is longer than an electric current-flowing path from the first switching chip 51 to the negative electrode terminal connection portion 24.

As described above, because an electric current-flowing path that runs through the first switching chip 51 and an electric current-flowing path that runs through the second switching chip 52 are different from each other, the first switching chip 51 and the second switching chip 52 have different impedances (e.g., resistance and inductance) from each other. When there is a difference in impedance between the switching chips that are arranged in parallel with each other, there is a likelihood that oscillation due to a difference in switching surge voltage or electric current imbalance will occur.

In contrast, the semiconductor module 100 according to the first embodiment has a structure in which the auxiliary conductor 72 and the auxiliary bonding wires 63 and 64 are provided.

The effects by the semiconductor module 100 according to the first embodiment are described with reference to FIG. 8. FIG. 8 is a partially exploded perspective diagram of the model portion 101 that is illustrated in FIG. 6. It is noted that for simplicity in FIG. 8 only the second switching chip 52 is illustrated.

Within the first substrate pattern 21, a collector side electric current IC2 flows from a positive electrode terminal connection portion 23 to a position to which a rear surface electrode of the second switching chip 52 is connected. As illustrated in FIG. 8, the collector side electric current IC2 to the second switching chip 52 flows in the vicinity of the auxiliary conductor 72.

The collector side electric current IC2 flows, as an emitter side electric current IE21, from the front surface electrode of the switching chip 52 to a negative electrode terminal connection portion 24, through the bonding wire 62 and the second substrate pattern 22.

At the same time, one portion of the collector side electric current IC2 flows, as an emitter side electric current IE22, from the front surface electrode of the switching chip 52 to the negative electrode terminal connection portion 24 through the first auxiliary bonding wire 63, the auxiliary conductor 72, the second auxiliary bonding wire 64, and the second substrate pattern 22.

The collector side electric current IC2 and the emitter side electric current IE22 face each other with the insulating plate 71 in between. Furthermore, directions in which the collector side electric current IC2 and the emitter side electric current IE22 flow are opposite to each other. For this reason, external magnetic fluxes that occur from the collector side electric current IC2 and the emitter side electric current IE22 cancel out each other. For this reason, it is possible that the model portion 101 of the semiconductor module reduces inductance. As a result, an inductance difference between the first switching chip 51 and the second switching chip 52 due to wiring shape differences can be reduced.

It is noted that based on a calculated results for an operating frequency of 1 GHz, the ratio of the inductances that occur in the first switching chip 51 and the second switching chip 52 is 122% in the model portion 105 of the semiconductor module according to the comparative example. In contrast, in the model portion 101 of the semiconductor module according to the first embodiment, the ratio of the inductances that occurs in the first switching chip 51 and the second switching chip 52 is 100.3%.

### Second Embodiment

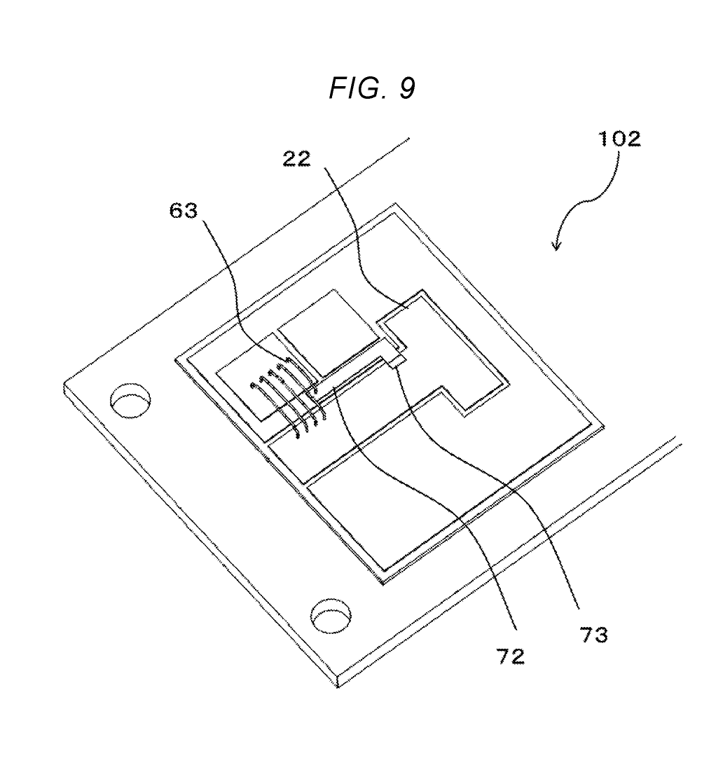

Next, a second embodiment is described with reference to FIG. 9. FIG. 9 is a perspective diagram illustrating one portion of an internal structure of the model portion 102 according to the second embodiment.

What distinguishes a model portion 102 from the model portion 101 is that the auxiliary conductor 72 in model portion 102 has a connection portion 73 in the. The connection portion 73 is connected to the second substrate pattern 22, for example, through a connection member, such as solder.

Not only in the model portion 101 of a semiconductor module according to the first embodiment, but also in the model portion 102 of a semiconductor module according to the second embodiment, the difference in inductance between the switching chips within the module can be reduced.

### Third Embodiment

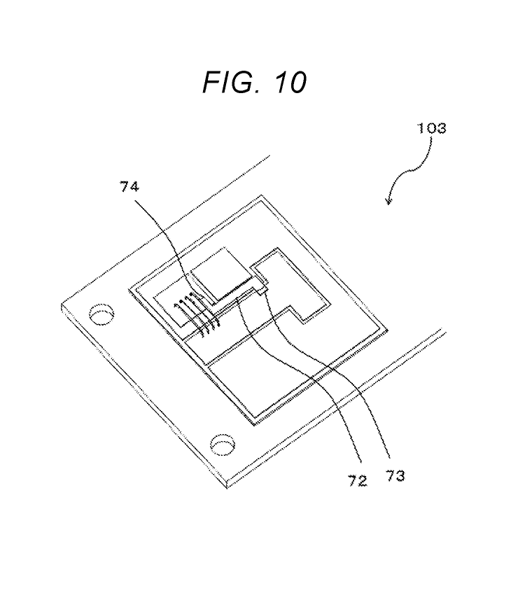

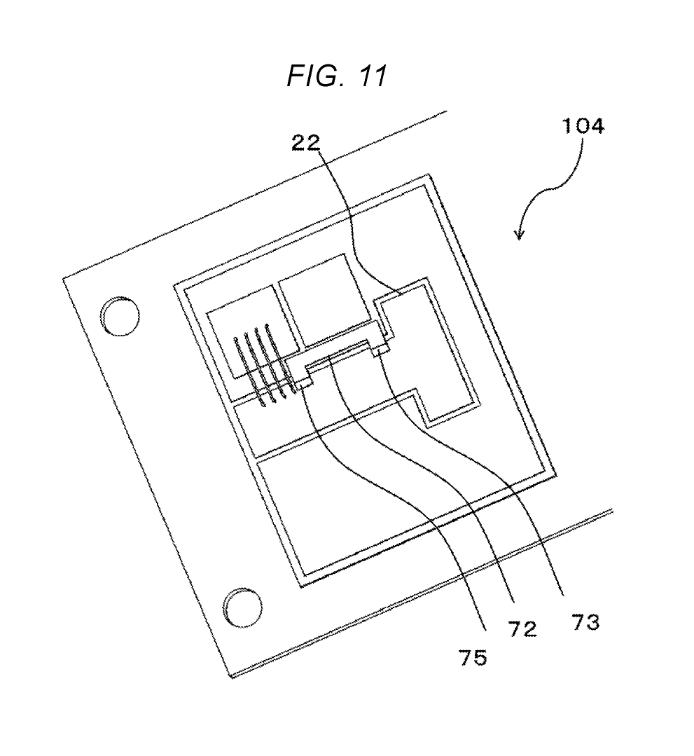

A third embodiment is described with reference to FIG. 10. FIG. 10 is a perspective diagram illustrating one portion of an internal structure of the model portion 103 according to the third embodiment.

What distinguishes a model portion 103 from the model portion 102 is that the auxiliary conductor 72 further has a connection portion 74. The connection portion 74 is connected to the front surface electrode of the second switching chip 52, for example, through a connection member, such as solder.

The model portion 103 of the semiconductor module according to the third embodiment does not use an auxiliary bonding wire, and because of this, has a simpler configuration.

### Fourth Embodiment

A fourth embodiment is described with reference to FIG. 11. FIG. 11 is a perspective diagram illustrating one portion of an internal structure of a model portion 104 of the semiconductor module according to the fourth embodiment.

What distinguishes the model portion 104 from the model portion 103 is that the auxiliary conductor 72 has a connection portion 75, and not the connection portion 74. The connection portion 73 and the connection portion 75 are connected to the second substrate pattern 22 through a connection member, such as a solder.

The model portion 104 of the semiconductor model according to the fourth embodiment has a simple configuration in which the auxiliary conductor 72 is connected to the second substrate pattern, and is otherwise the same as the model portion 101 and the model portion 103 in that as a result of an operation of canceling out magnetic fluxes between the auxiliary conductor 72 and the second substrate pattern 22 of the insulating substrate 2, an effect of reducing the inductance can be expected.

It is noted that the embodiments of the present disclosure are not limited to the examples as described above, and in implementation, constituent elements can be modified within a scope that does not depart from the gist of the present disclosure. For example, in the example embodiments, two switching chips are arranged adjacent to each other in parallel, but it is also possible that three or more switching chips can be arranged in parallel with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor module, comprising:
a plurality of insulating substrates each having a first conductive pattern and a second conductive pattern on a surface thereof;
a positive electrode terminal plate that electrically connects first conductive patterns on a pair of neighboring insulating substrates of the plurality of insulating substrates;
a negative electrode terminal plate that electrically connects second conductive patterns on the pair of neighboring insulating substrates, the negative electrode terminal plate being connected to a negative electrode terminal connection portion of each second conductive pattern on the pair of neighboring insulating substrates;
a first switching chip on a first conductive pattern of one of the pair of neighboring insulating substrate and having a front surface electrode on a side of the first switching chip facing away from the first conductive pattern;
a second switching chip on the first conductive pattern, the first switching chip being between the negative electrode terminal connection portion and the second switching chip, the second switching chip having a front surface electrode;
a first bonding wire that connects the front surface electrode of the first switching chip and the second conductive pattern;
a second bonding wire that connects the front surface electrode of the second switching chip and the second conductive pattern;
an insulating plate on the first conductive pattern and between both the first and second switching chips and the second conductive pattern;
an auxiliary conductor on the insulating plate;
a first auxiliary connection that electrically connects the auxiliary conductor and the front surface electrode of the second switching chip; and
a second auxiliary connection that connects the auxiliary conductor and the second conductive pattern.

2. The semiconductor module according to claim 1, wherein the first auxiliary connection is a first auxiliary bonding wire having one end connected to the front surface electrode of the second switching chip and another end connected to the auxiliary conductor.

3. The semiconductor module according to claim 2, wherein the second auxiliary connection is a second auxiliary bonding wire having one end connected to the auxiliary conductor and another end connected to the second conductive pattern.

4. The semiconductor module according to claim 2, wherein the second auxiliary connection is a solder between the auxiliary conductor and the second conductive pattern.

5. The semiconductor module according to claim 1, wherein the second auxiliary connection is a solder between the auxiliary conductor and the second conductive pattern.

6. The semiconductor module according to claim 1, wherein the first auxiliary connection is a first solder between the auxiliary conductor and the front surface electrode of the second switching chip.

7. The semiconductor module according to claim 6, wherein the second auxiliary connection is a second solder between the auxiliary conductor and the second conductive pattern.

8. The semiconductor module according to claim 1, wherein the first auxiliary connection is a first solder between the auxiliary conductor and the second conductive pattern and electrical connection between the auxiliary conductor and the front surface electrode of the second switching chip is through the first solder, the second conductive pattern, and the second bonding wire.

9. The semiconductor module according to claim 8, wherein the second auxiliary connection is a second solder between the auxiliary conductor and the second conductive pattern.

10. The semiconductor module according to claim 1, wherein
the first and second switching chips are spaced from each other in a first direction,
the auxiliary conductor is between the first switching circuit and a portion of the second conductive pattern in a second direction perpendicular to the first direction.

11. An inverter device including the semiconductor module according to claim 1.

12. A semiconductor module, comprising:
a first insulating substrate;
a second insulating substrate adjacent to the first insulating substrate in a first direction, the first and second insulating substrates each respectively having a first conductive pattern and a second conductive pattern on a surface thereof;
a positive electrode terminal plate that electrically connects the first conductive patterns on the first and second insulating substrates;
a negative electrode terminal plate that electrically connects the second conductive patterns on the first and second insulating substrates, the negative electrode terminal plate being connected to a negative electrode terminal connection portion of the second conductive patterns;
a first switching chip on the first conductive pattern of the first insulating substrate and having a front surface electrode on side of the first switching chip facing away from the first conductive pattern;
a second switching chip on the first conductive pattern of the first insulating substrate, the first switching chip being between the negative electrode terminal connection portion and the second switching chip in the first direction, the second switching chip having a front surface electrode;
a first bonding wire that connects the front surface electrode of the first switching chip and the second conductive pattern of the first insulating substrate;
a second bonding wire that connects the front surface electrode of the second switching chip and the second conductive pattern of the first insulating substrate;
an insulating plate on the first conductive pattern of the first insulating substrate and between both the first and second switching chips and the second conductive pattern of the first insulating substrate in a second direction perpendicular to the first direction;
an auxiliary conductor on the insulating plate;
a first auxiliary connection that electrically connects the auxiliary conductor and the front surface electrode of the second switching chip; and
a second auxiliary connection that connects the auxiliary conductor and the second conductive pattern of the first insulating substrate.

13. The semiconductor module according to claim 12, wherein
the first auxiliary connection is a first auxiliary bonding wire having one end connected to the front surface electrode of the second switching chip and another end connected to the auxiliary conductor, and
the second auxiliary connection is a second auxiliary bonding wire having one end connected to the auxiliary conductor and another end connected to the second conductive pattern of the first insulating substrate.

14. The semiconductor module according to claim 12, wherein the second auxiliary connection is a first solder between the auxiliary conductor and the second conductive pattern of the first insulating substrate.

15. The semiconductor module according to claim 14, wherein the first auxiliary connection is a second solder between the auxiliary conductor and the front surface electrode of the second switching chip.

16. The semiconductor module according to claim 14, wherein
the first auxiliary connection is a second solder between the auxiliary conductor and the second conductive pattern of the first insulating substrate, and
electrical connection between the auxiliary conductor and the front surface electrode of the second switching chip is through the second solder, the second conductive pattern, and the second bonding wire.

17. A semiconductor module, comprising:
a base plate;
a pair of insulating substrates on the base plate, the insulating substrates being adjacent to each other in a first direction, the insulating substrates each having a first conductive pattern and a second conductive pattern thereon;
each insulating substrate having:
a negative electrode terminal portion of the second conductive pattern, the negative electrode terminal portion being on a portion of the insulating substrate adjacent to the other insulating substrate of the pair in the first direction;
a first switching chip on the first conductive pattern and having a front surface electrode;
a second switching chip on the first conductive pattern between the negative electrode terminal connection portion and the second switching chip in the first direction, the second switching chip having a front surface electrode;
a first bonding wire that connects the front surface electrode of the first switching chip and the second conductive pattern;
a second bonding wire that connects the front surface electrode of the second switching chip and the second conductive pattern;
an insulating plate between both the first and second switching chips and the second conductive pattern in a second direction perpendicular to the first direction;
an auxiliary conductor on the insulating plate;
a first auxiliary connection that electrically connects the auxiliary conductor and the front surface electrode of the second switching chip; and
a second auxiliary connection that connects the auxiliary conductor and the second conductive pattern; and
a positive electrode terminal plate that electrically connects the first conductive patterns of the pair of insulating substrates; and
a negative electrode terminal plate that electrically connects the second conductive patterns of the pair of insulating substrates, the negative electrode terminal plate being connected to the negative electrode terminal connection portion of the second conductive patterns.

18. The semiconductor module according to claim 17, wherein
the first auxiliary connection is a first auxiliary bonding wire having one end connected to the front surface electrode of the second switching chip and another end connected to the auxiliary conductor, and
the second auxiliary connection is a second auxiliary bonding wire having one end connected to the auxiliary conductor and another end connected to the second conductive pattern of the first insulating substrate.

19. The semiconductor module according to claim 17, wherein the second auxiliary connection is a solder between the auxiliary conductor and the second conductive pattern.

20. The semiconductor module according to claim 17, wherein the first auxiliary connection is a solder.
